(19) United States
(12) Patent Application Publication
(10) Pub. No.: US 2008/0301520 A1
(43) Pub. Date: Dec. 4, 2008

(54) Method and apparatus for recording information on recording medium

(75) Inventor: Seiji Higurashi, Tokyo-to (JP)

Correspondence Address: LOUIS WOO;LAW OFFICE OF LOUIS WOO, 717 NORTH FAYETTE STREET, ALEXANDRIA, VA, 22314, US

(73) Assignee: Victor Company of Japan, Ltd., Yokohama (JP)

(21) Appl. No.: 12/155,091

(22) Filed: May 29, 2008

(30) Foreign Application Priority Data
Jun. 1, 2007 (JP) 2007-146524

(51) Int. Cl. H03M 13/29; G06F 11/08

(52) U.S. Cl. 714/755; 369/47.1; 714/E11.03

(57) ABSTRACT

A fixed-length block is repetitively generated. The fixed-length block includes a sync information piece, “n-m” information pieces following the sync information piece, an ID information piece following the “n-m” information pieces, and “m” information pieces following the ID information piece, where “n” denotes a natural number equal to or greater than 2, and “m” denotes a natural number smaller than “n” and equal to or greater than 1. The generated fixed-length block is recorded on a recording medium. The ID information piece is placed in an intermediate portion of the fixed-length block.

### BACKGROUND OF THE INVENTION

1. Field of the Invention

This invention generally relates to a method and an apparatus for recording information on a recording medium. This invention particularly relates to a method and an apparatus for recording main information signals of plural types and a sync information signal on a recording medium such as an optical disc.

2. Description of the Related Art

A DVD-RW (Digital Versatile Disc Rewritable) has an information recording area formed with a spiral of a groove and a spiral of a land. A portion of the groove is located between neighboring portions of the land as viewed in a radial direction of the disc. A groove portion and a pair of land portions adjoining the groove portion constitute a portion of a spiral track.

Main information can be recorded on and reproduced from the groove on a block-by-block basis, where “block” means an ECC (error correction code) block. Auxiliary information is previously recorded on the land. Specifically, the auxiliary information is represented by pre-pits formed in the land. While a groove portion is scanned by a laser beam, land portions adjoining the groove portion is scanned also.

The auxiliary information is divided into blocks positionally adjacent and corresponding to groove portions assigned to ECC blocks of the main information, respectively. Each auxiliary information block contains a signal representing the address of a corresponding groove portion assigned to an ECC block of the main information, and also an error correction code signal for the address signal.

During the recording of the main information on the DVD-RW or the reproduction of the main information therefrom, the auxiliary information is read from the DVD-RW. The address signal is recovered from the read auxiliary information through a signal separation process and an error correction process. The position of the currently-accessed groove portion assigned to an ECC block of the main information is detected by referring to the recovered address signal.

It is desirable to reduce the number of bits of the auxiliary information per disc. Furthermore, it is desirable to quickly recover the address signal from the read auxiliary information. The quick recovery of the address signal is convenient for search.

### SUMMARY OF THE INVENTION

It is a first object of this invention to provide an improved method of recording information on a recording medium.

It is a second object of this invention to provide an improved apparatus for recording information on a recording medium.

A first aspect of this invention provides a method of recording information on a recording medium. The method comprises the steps of repetitively generating a fixed-length block including a sync information piece, “n-m” information pieces following the sync information piece, an ID information piece following the “n-m” information pieces, and “m” information pieces following the ID information piece, wherein “n” denotes a natural number equal to or greater than 2, and “m” denotes a natural number smaller than “n” and equal to or greater than 1; and recording the generated fixed-length block on the recording medium. The ID information piece is placed in an intermediate portion of the fixed-length block.

A second aspect of this invention provides a method of recording information on a recording medium. The method comprises the steps of repetitively generating a fixed-length block including a sync information piece, “n-m” information pieces following the sync information piece, a first error correction code signal following the “n-m” information pieces, an ID information piece following the first error correction code signal, “m” information pieces following the ID information piece, and a second error correction code signal following the “m” information pieces, wherein “n” denotes a natural number equal to or greater than 2, and “m” denotes a natural number smaller than “n” and equal to or greater than 1, wherein the first error correction code signal is for error correction about the “n-m” information pieces and the ID information piece, and the second error correction code signal is for error correction about the “m” information pieces and the ID information piece, and wherein the ID information piece is for identification about types of the “n-m” information pieces and the “m” information pieces; and recording the generated fixed-length block on the recording medium. The ID information piece is placed in an intermediate portion of the fixed-length block.

A third aspect of this invention is based on the second aspect thereof, and provides a method wherein the “n-m” information pieces, the first error correction code signal, and the ID information piece constitute a first linear cyclic error correction code word, and the ID information piece, the “m” information pieces, and the second error correction code signal constitute a second linear cyclic error correction code word.

A fourth aspect of this invention provides an apparatus for recording information on a recording medium. The apparatus comprises means for repetitively generating a fixed-length block including a sync information piece, “n-m” information pieces following the sync information piece, an ID information piece following the “n-m” information pieces, and “m” information pieces following the ID information piece, wherein “n” denotes a natural number equal to or greater than 2, and “m” denotes a natural number smaller than “n” and equal to or greater than 1; and means for recording the generated fixed-length block on the recording medium. The ID information piece is placed in an intermediate portion of the fixed-length block.

A fifth aspect of this invention provides an apparatus for recording information on a recording medium. The apparatus comprises means for repetitively generating a fixed-length block including a sync information piece, “n-m” information pieces following the sync information piece, a first error correction code signal following the “n-m” information pieces, an ID information piece following the first error correction code signal, “m” information pieces following the ID information piece, and a second error correction code signal following the “m” information pieces, wherein “n” denotes a natural number equal to or greater than 2, and “m” denotes a natural number smaller than “n” and equal to or greater than 1, wherein the first error correction code signal is for error correction about the “n-m” information pieces and the ID information piece, and the second error correction code signal is for error correction about the “m” information pieces and the ID information piece, and wherein the ID information piece is for identification about types of the “n-m” information pieces and the “m” information pieces; and means for recording the generated fixed-length block on the recording medium. The ID information piece is placed in an intermediate portion of the fixed-length block.

A sixth aspect of this invention is based on the fifth aspect thereof, and provides an apparatus wherein the “n-m” information pieces, the first error correction code signal, and the ID information piece constitute a first linear cyclic error correction code word, and the ID information piece, the “m” information pieces, and the second error correction code signal constitute a second linear cyclic error correction code word.

This invention provides the following advantages. The ID information piece can be used for detecting not only the “n-m” information pieces but also the “m” information pieces in the fixed-length block. Therefore, the ID information pieces use fewer bits in whole recorded information so that the number of bits constituting the whole recorded information can be smaller. On the other hand, the trace length for obtaining one piece of information is equal to that in the case of a prior-art design.

Error correction about the “n-m” information pieces and the ID information piece can be implemented in response to the first error correction code signal. Error correction about the “m” information pieces and the ID information piece can be implemented in response to the second error correction code signal. The trace length for obtaining one piece of information is reasonable. In the case where the “n-m” information pieces and the “m” information pieces represent an ECC block address, a currently-accessed ECC block address can be properly detected during search.

### BRIEF DESCRIPTION OF THE DRAWINGS

FIG. 1 is a diagram of a portion of a prior-art optical disc.

FIG. 2 is a diagram of the relation between the states of a land pre-pit set and information pieces assigned thereto in the prior-art optical disc.

FIG. 3 is a diagram of the relation between a recorded sector and land pre-pits in the prior-art optical disc.

FIG. 4 is a diagram of the structure of one land pre-pit block in a prior-art design.

FIG. 5 is a diagram of the structure of one land pre-pit block in a conceivable design.

FIG. 6 is a block diagram of an information recording apparatus according to a first embodiment of this invention.

FIG. 7 is a diagram of the structure of one land pre-pit block generated and recorded by the apparatus of FIG. 6.

FIG. 8 is a time-domain diagram of information pieces sequentially reproduced from land pre-pits recorded by the apparatus of FIG. 6.

FIG. 9 is a block diagram of an information recording apparatus according to a second embodiment of this invention.

FIG. 10 is a diagram of the structure of one land pre-pit block generated and recorded by the apparatus of FIG. 9.

FIG. 11 is a block diagram of an error correction code generator in FIG. 9.

FIG. 12 is a time-domain diagram of the waveforms of control signals in the error correction code generator of FIG. 11.

FIG. 13 is a time-domain diagram of information pieces sequentially reproduced from land pre-pits recorded by the apparatus of FIG. 9.

FIG. 14 is a diagram of the relation between two sub words of a linear cyclic error correction code in a third embodiment of this invention.

### DETAILED DESCRIPTION OF THE INVENTION

A prior-art optical disc and a conceivable optical disc will be explained below for a better understanding of this invention.

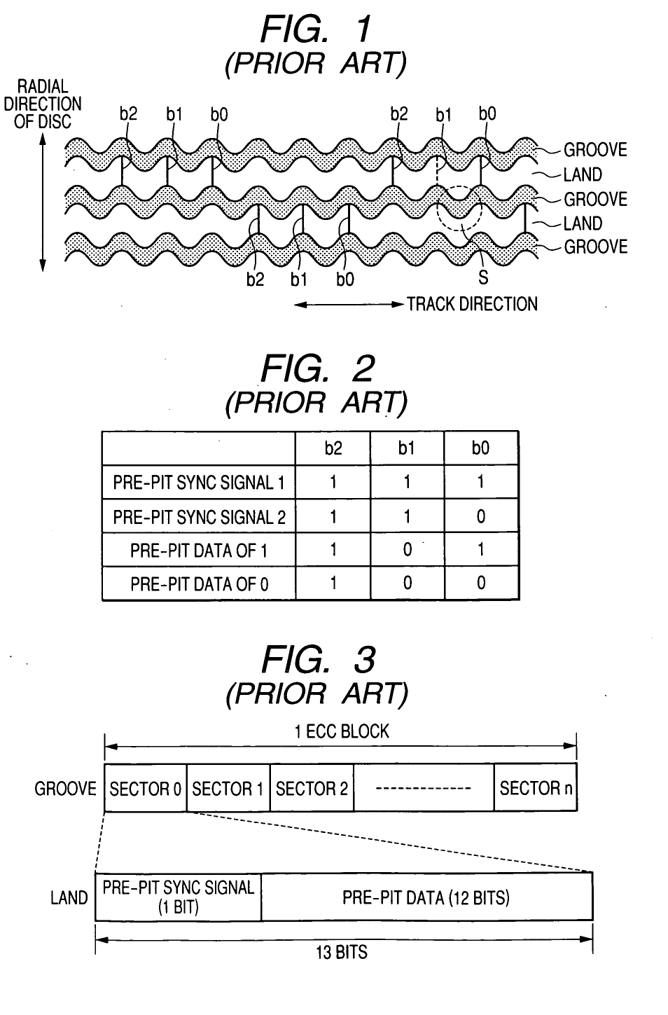

FIG. 1 shows a portion of a prior-art optical disc having groove portions and land portions which alternate as viewed along a radial direction of the disc. A groove portion and a pair of land portions adjoining the groove portion constitute a portion of a spiral track. Alternatively, the groove portions and the land portions may be in sets forming concentric tracks.

In the prior-art optical disc of FIG. 1, the groove portions are designed to store main information. Side walls defining the groove portions wobble at a small amplitude measured in the radial direction of the disc. The wobble is constant in spatial frequency and period. A disc drive device detects the wobble, and utilizes the detected wobble in accurately controlling disc rotation and correctly reading address information from the disc.

In the prior-art optical disc of FIG. 1, sets each having three adjacent land pre-pits b0, b1, and b2 are formed in the land portions at a stage of the manufacture of the disc. In each set, the land pre-pits b0, b1, and b2 are spaced along a longitudinal direction of the track at intervals equal to the period of the wobble. The land pre-pit sets are designed to indicate auxiliary information. Thus, the auxiliary information is recorded on the disc as the land pre-pit sets at the stage of the manufacture of the disc. The land pre-pits in each set are sequentially scanned by the disc drive device in the order as b2→b1→b0.

In each set, the land pre-pits b0 and b1 may be absent. The presence and absence of a land pre-pit are denoted by “1” and “0”, respectively.

With reference to FIG. 2, each land pre-pit set is in one chosen from four different states assigned to different 1-bit signals respectively. Specifically, in a first state of a set, the land pre-pits b2, b1, and b0 are “1”. The first state of a set is assigned to a pre-pit sync signal “1” having one bit. In a second state of a set, the land pre-pits b2, b1, and b0 are “1”, “1”, and “0”, respectively. The second state of a set is assigned to a pre-pit sync signal “2” having one bit. In a third state of a set, the land pre-pits b2, b1, and b0 are “1”, “0”, and “1”, respectively. The third state of a set is assigned to a pre-pit data bit of “1”. In a fourth state of a set, the land pre-pits b2, b1, and b0 are “1”, “0”, and “0”, respectively. The fourth state of a set is assigned to a pre-pit data bit of “0”. Thus, when the land pre-pit b1 is “1”, the related set indicates the pre-pit sync signal “1” or “2”. When the land pre-pit b1 is “0”, the related set indicates a land pre-pit data bit of “1” or “0”. In this case, when the associated land pre-pit b0 is “1”, the set indicates a land pre-pit data bit of“1”. On the other hand, when the associated land pre-pit b0 is “0”, the set indicates a land pre-pit data bit of “0”.

Main information can be recorded on and reproduced from the groove or grooves of the prior-art optical disc of FIG. 1 on a block-by-block basis, where “block” means an ECC (error correction code) block. As shown in FIG. 3, one ECC block is composed of n+1 successive sectors each having a fixed length, where “n” denotes a predetermined natural number equal to, for example, 31. Each of land portions corresponding and adjacent to the respective sectors on the groove or grooves has 13-bit data (a sync block or a pre-pit data block) recorded as land pre-pits. Specifically, the 13-bit data consists of a 1-bit pre-pit sync signal represented by one set of the land pre-pits b2, b1, and b0, and 12-bit pre-pit data represented by twelve sets of the land pre-pits b2, b1, and b0.

With reference to FIG. 1, during the recording of main information on the optical disc or the reproduction of main information therefrom, a forward light beam is focused into a spot S on the optical disc before being reflected by the optical disc and then forming a return light beam. The light spot S covers not only a portion of a groove to be scanned but also portions of two lands extending adjacently along the two sides of the groove portion. Therefore, while the groove is scanned by the light spot S, land pre-pits in the two adjacent lands are scanned also. A photodetector of, for example, a quadrant type receives the return light beam, and changes the received light beam into a reproduced electric signal through photoelectric conversion. The reproduced signal undergoes prescribed processing to obtain a signal representing detected land pre-pits. A detection output signal for land pre-pits in one of the two lands adjacent to the groove of interest is subtracted from a detection output signal for land pre-pits in the other land. In this case, a land pre-pit detection signal corresponding to one of the two lands has a positive polarity while a land pre-pit detection signal corresponding to the other land has a negative polarity. Accordingly, it is possible to discriminate between the two lands.

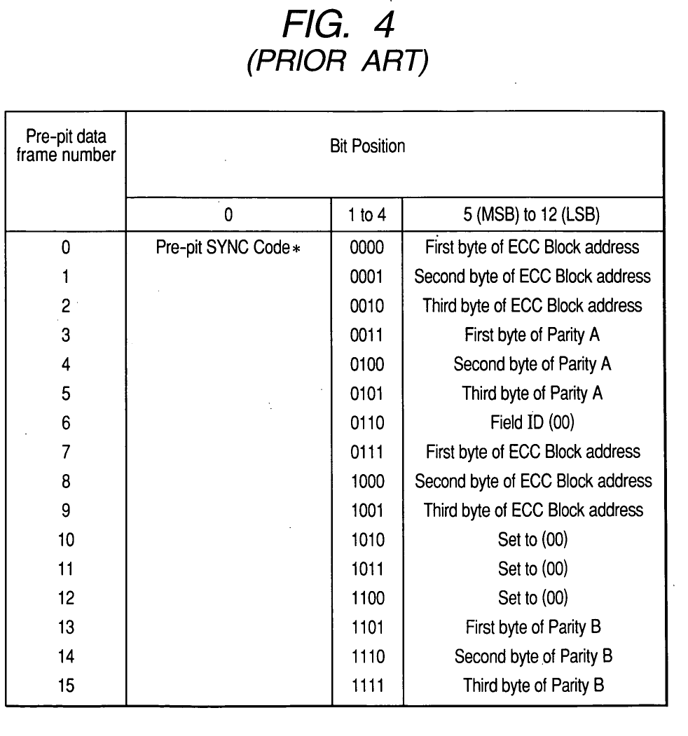

A DVD-RW (Digital Versatile Disc Rewritable) is an example of the prior-art optical disc of FIG. 1. In the DVD-RW, auxiliary information represented by land pre-pits is divided into blocks (land pre-pit blocks) which are classified according to field ID. One land pre-pit block with a field ID of “00000000” has a structure shown in FIG. 4. The land pre-pit block structure of FIG. 4 is disclosed in Standard ECMA-338, “80 mm (1.46 Gbytes per side) and 120 mm (4.70 Gbytes per side) DVD Re-recordable Disk (DVD-RW).

With reference to FIG. 4, frame numbers “0”, “1”, . . . “15” are given to 16 successive sectors, respectively. In 13-bit data (a sync block or a pre-pit data block) represented by land pre-pits and corresponding to one sector, the bit positions are denoted by “0”, “1”, . . . , “12” respectively along the direction from MSB to LSB. One land pre-pit block corresponds to 16 successive sectors, and is composed of 16 pre-pit data blocks assigned to the 16 successive sectors respectively. Since each of the 16 pre-pit data blocks has 13 bits, the number of bits of the land pre-pit block is 208.

In each pre-pit data block, the bit position “0”, that is, the first bit position, is assigned to a pre-pit sync signal (a pre-pit sync code) having one bit. The bit positions “1” to “4” are assigned to a 4-bit address representing the position of the pre-pit data block relative to the related land pre-pit block. The bit positions “5” to “12” are assigned to 8-bit information (1-byte information) decided by the related land pre-pit block address and representing, for example, a portion of an ECC block address, a portion of a parity, or a field ID. For example, the first byte of an ECC block address is recorded in the pre-pit data block at an address of “0000” and the pre-pit data block at an address of “0111” within the land pre-pit block. The pre-pit sync code in FIG. 4 is one of the pre-pit sync signal “1” and the pre-pit sync signal “2” in FIG. 2. For example, the pre-pit sync signal “1” is recorded in each of first alternate ones of land pre-pit blocks while the pre-pit sync signal “2” is recorded in each of second alternate ones thereof.

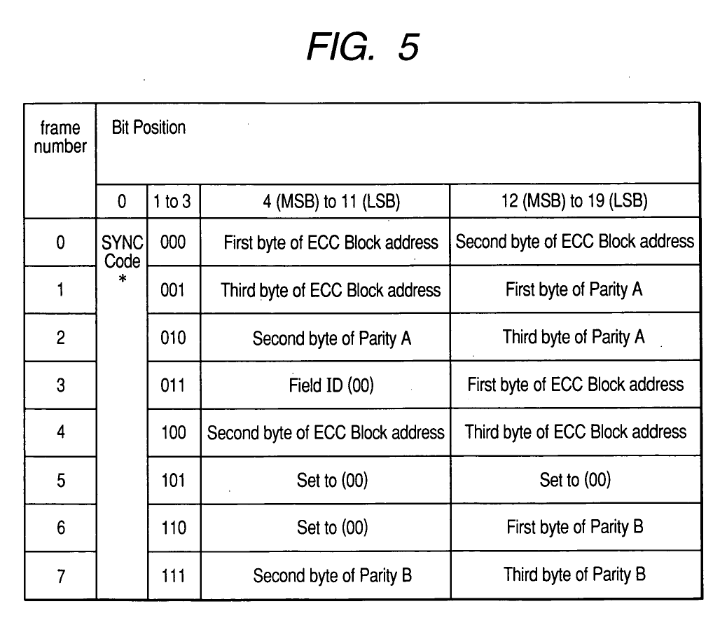

To reduce the number of bits per land pre-pit block, it is conceivable to replace the land pre-pit block having the structure of FIG. 4 with a land pre-pit block having a structure of FIG. 5. It should be noted that the land pre-pit block structure of FIG. 5 is not prior art to this invention. The number of bits representing an address relative to the land pre-pit block in FIG. 5 is three, whereas the number of bits representing an address relative to the land pre-pit block in FIG. 4 is four. The land pre-pit block in FIG. 5 is composed of 8 pre-pit data blocks each for storing 2-byte information. The 8 pre-pit data blocks are assigned frame numbers “0”, “1”, . . . , “7” respectively. In FIG. 5, each pre-pit data block has 20 bits rather than 13 bits. Accordingly, the land pre-pit block in FIG. 5 has 160 bits. In each 20-bit pre-pit data block, the bit positions are denoted by “0”, “1”, . . . , “19” respectively along the direction from MSB to LSB.

With reference to FIG. 5, in each pre-pit data block, the bit position “0”, that is, the first bit position, is assigned to a pre-pit sync signal (a sync code) having one bit. The bit positions “1” to “3” are assigned to a 3-bit address representing the position of the pre-pit data block relative to the related land pre-pit block. The bit positions “4” to “19” are assigned to 2-byte information.

The land pre-pit block in FIG. 5 has 8 pre-pit data blocks each storing 2-byte information. Thus, the land pre-pit block in FIG. 5 stores 16-byte information. On the other hand, the land pre-pit block in FIG. 4 has 16 pre-pit data blocks each storing 1-byte information. Thus, the land pre-pit block in FIG. 4 stores 16-byte information also. Although the land pre-pit block in FIG. 5 and that in FIG. 4 are equal in the number of bits of recorded information as indicated above, the land pre-pit block in FIG. 5 has 160 bits in total while that in FIG. 4 has 208 bits in total.

According to the land pre-pit block structure of FIG. 5, the trace length for obtaining one piece of information (data) is equal to 19 bits. On the other hand, according to the land pre-pit block structure of FIG. 4, the trace length is equal to 12 bits. A greater trace length tends to cause obtaining data to be difficult during search.

According to the land pre-pit block structure of FIG. 4 or FIG. 5, an error check on a detected ECC block address can be started and implemented provided that all information pieces up to the third byte of a parity B have been sequentially read out. Therefore, a long time is taken until an address decision is implemented for every ECC block. Such a long time tends to cause a problem during search.

This invention has been carried out to remove the above-mentioned drawbacks in the prior-art and conceivable designs. Specifically, the number of bits of one land pre-pit block in this invention is smaller than that in the prior-art design of FIG. 4 while the trace length for obtaining one piece of information (data) in this invention is equal to that in the prior-art design of FIG. 4. This invention allows an error correction code to be efficiently added in order to complete each land pre-pit block. This invention enables an address decision to be properly implemented during search.

### First Embodiment

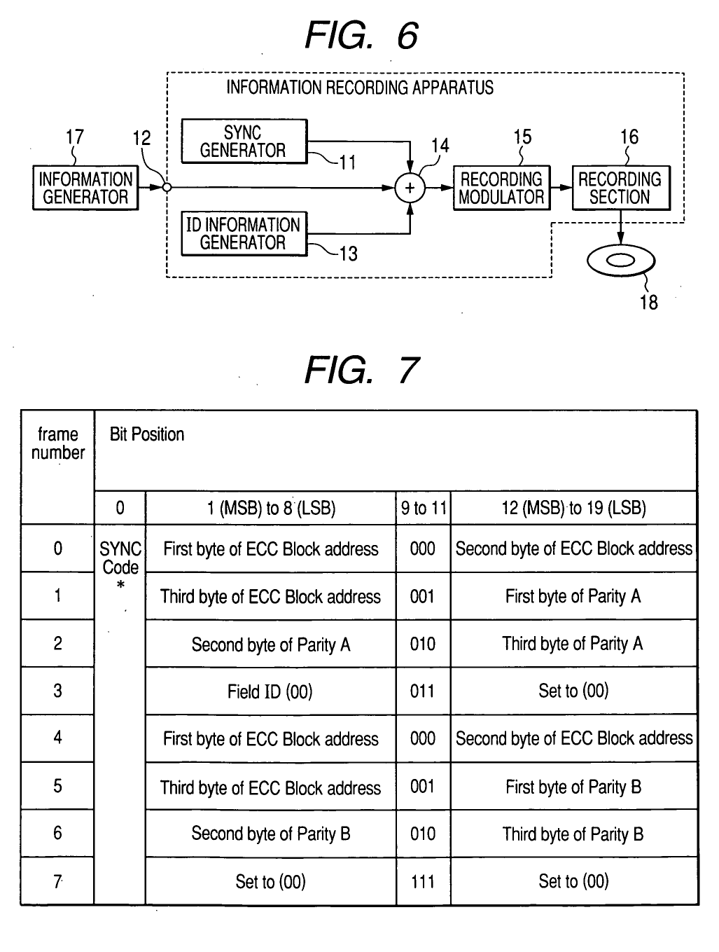

FIG. 6 shows an information recording apparatus according to a first embodiment of this invention.

The apparatus of FIG. 6 includes a sync generator 11, an input terminal 12, an ID information generator 13, an adder 14, a recording modulator 15, and a recording section 16.

The sync generator 11 produces a 1-bit pre-pit sync signal (a 1-bit pre-pit sync code) taking a predetermined value or state. The sync generator 11 feeds the produced 1-bit pre-pit sync signal to the adder 14. Subsequently, a first 1-byte information piece is fed via the input terminal 12 to the adder 14. The first 1-byte information piece is generated by and transmitted from, for example, an external information generator 17. Thereafter, the ID information generator 13 produces a 3-bit ID information piece, and feeds the produced 3-bit ID information piece to the adder 14. Subsequently, a second 1-byte information piece is fed via the input terminal 12 to the adder 14. The second 1-byte information piece is generated by and transmitted from, for example, the external information generator 17. In this way, the 1-bit pre-pit sync signal, the first 1-byte information piece, the 3-bit ID information piece, and the second 1-byte information piece are sequentially fed to the adder 14. The 1-bit pre-pit sync signal, the first 1-byte information piece, the 3-bit ID information piece, and the second 1-byte information piece are sequentially connected or combined by the adder 14 in that order to form a pre-pit data block. The adder 14 outputs the pre-pit data block.

It should be noted that the external information generator 17 may be provided within the apparatus of FIG. 6.

The sequential feed of the 1-bit pre-pit sync signal, the first 1-byte information piece, the 3-bit ID information piece, and the second 1-byte information piece to the adder 14 is repeated 8 times so that 8 pre-pit data blocks constituting one land pre-pit block are sequentially generated by and outputted from the adder 14. The first 1-byte information piece, the 3-bit ID information piece, and the second 1-byte information piece are updated for each pre-pit data block. The above-mentioned set of operation steps to generate one land pre-pit block is periodically iterated so that land pre-pit blocks are sequentially generated by and outputted from the adder 14.

The pre-pit data blocks are of a fixed length. In addition, the land pre-pit blocks are of a fixed length.

The 3-bit ID information piece in each pre-pit data block includes an ID for the pre-pit data block or an ID information piece representing the types of the first 1-byte information piece and the second 1-byte information piece in the pre-pit data block. The 3-bit ID information piece in each pre-pit data block may include an address information piece representing the address of the pre-pit data block relative to the related land pre-pit block. The 3-bit ID information piece in each pre-pit data block takes one among predetermined values or states.

The first 1-byte information piece in each pre-pit data block represents, for example, a portion of an ECC block address, a portion of a parity, or a field ID. The second 1-byte information piece in each pre-pit data block represents, for example, a portion of an ECC block address or a portion of a parity.

FIG. 7 shows an example of the structure of one land pre-pit block outputted from the adder 14. Land pre-pit blocks are classified according to field ID. The structure of FIG. 7 is applied to a land pre-pit block having a field ID of “00000000”.

As shown in FIG. 7, one land pre-pit block is composed of 8 pre-pit data blocks each having 20 bits. The 8 pre-pit data blocks are assigned frame numbers “0”, “1”, . . . , “7” respectively. In each pre-pit data block, the bit positions are denoted by “0”, “1”, . . . , “19” respectively along the direction from MSB to LSB. In each pre-pit data block, the 1-bit pre-pit sync signal (the 1-bit pre-pit sync code), the first 1-byte information piece, the 3-bit ID information piece, and the second 1-byte information piece are successively arranged. The 1-bit pre-pit sync signal occupies the bit position “0”. The first 1-byte information piece occupies the bit position “1” to the bit position “8”. The 3-bit ID information piece occupies the bit position “9” to the bit position “11”. The second 1-byte information piece occupies the bit position “12” to the bit position “19”.

With reference to FIG. 7, in each land pre-pit block, the first and second 1-byte information pieces in the first pre-pit data block represent the first and second bytes of an ECC block address, respectively. The first and second 1-byte information pieces in the second pre-pit data block represent the third byte of the ECC block address and the first byte of a parity “A”. The first and second 1-byte information pieces in the third pre-pit data block represent the second and third bytes of the parity “A”. The parity “A” is designed for error correction about the first and second 1-byte information pieces in the first pre-pit data block, the first 1-byte information piece in the second pre-pit data block, and the 3-bit ID information pieces in the first, second, and third pre-pit data blocks. Thus, the parity “A” is designed for error correction about the ECC block address represented by the first and second pre-pit data blocks and the 3-bit ID information pieces in the first, second, and third pre-pit data blocks.

In each land pre-pit block (FIG. 7), the first information piece in the fourth pre-pit data block represents a field ID. The first and second 1-byte information pieces in the fifth pre-pit data block represent the first and second bytes of the ECC block address, respectively. The first and second 1-byte information pieces in the sixth pre-pit data block represent the third byte of the ECC block address and the first byte of a parity “B”. The first and second 1-byte information pieces in the seventh pre-pit data block represent the second and third bytes of the parity “B”. The parity “B” is designed for error correction about the first and second 1-byte information pieces in the fourth and fifth pre-pit data blocks, the first 1-byte information piece in the sixth pre-pit data block, and the 3-bit ID information pieces in the fourth, fifth, sixth, and seventh pre-pit data blocks. Thus, the parity “B” is designed for error correction about the field ID, the ECC block address represented by the fifth and sixth pre-pit data blocks, and the 3-bit ID information pieces in the fourth, fifth, sixth, and seventh pre-pit data blocks.

As shown in FIG. 7, the 3-bit ID information piece in the first pre-pit data block takes a value or state of “000” indicating that the first and second 1-byte information pieces in the first pre-pit data block represent the first and second bytes of an ECC block address respectively. The 3-bit ID information piece in the second pre-pit data block takes a value or state of “001” indicating that the first and second 1-byte information pieces in the second pre-pit data block represent the third byte of an ECC block address and the first byte of a parity respectively. The 3-bit ID information piece in the third pre-pit data block takes a value or state of “010” indicating that the first and second 1-byte information pieces in the third pre-pit data block represent the second and third bytes of a parity respectively. The 3-bit ID information piece in the fourth pre-pit data block takes a value or state of “011” indicating that the first and second 1-byte information pieces in the fourth pre-pit data block represent a field ID and a value of “00000000” respectively. The 3-bit ID information piece in the fifth pre-pit data block takes a value or state of “000” indicating that the first and second 1-byte information pieces in the fifth pre-pit data block represent the first and second bytes of an ECC block address respectively. The 3-bit ID information piece in the sixth pre-pit data block takes a value or state of “001” indicating that the first and second 1-byte information pieces in the sixth pre-pit data block represent the third byte of an ECC block address and the first byte of a parity respectively. The 3-bit ID information piece in the seventh pre-pit data block takes a value or state of “010” indicating that the first and second 1-byte information pieces in the seventh pre-pit data block represent the second and third bytes of a parity respectively. The 3-bit ID information piece in the eighth pre-pit data block takes a value or state of “111” indicating that each of the first and second 1-byte information pieces in the eighth pre-pit data block represents a value of “00000000”.

With reference back to FIG. 6, the recording modulator 15 receives an output signal (a sequence of land pre-pit blocks) from the adder 14. The recording modulator 15 subjects the output signal from the adder 14 to modulation of a predetermined system. Thereby, the recording modulator 15 converts the output signal from the adder 14 into a modulation-result signal of a prescribed format. The recording modulator 15 feeds the modulation-result signal to the recording section 16. The recording section 16 makes an optical disc 18 in response to the modulation-result signal. Specifically, the recording section 16 records the modulation-result signal on a land or lands of the optical disc 18 as land pre-pits therein. Accordingly, the land or lands of the optical disc 18 has land pre-pits representing the modulation-result signal.

The optical disc 18 is a recording medium. The optical disc 18 is, for example, a DVD-RW (Digital Versatile Disc Rewritable). The optical disc 18 may have at least one groove and at least one land similar to those in FIG. 1. The pre-pits are formed in the land or lands of the optical disc 18. These land pre-pits are grouped into sets each having three adjacent land pre-pits which may be similar to the land pre-pits b0, b1, and b2 in FIG. 1.

The recording section 16 may include a conventional stamper making machine and a conventional replicating machine. In this case, the stamper making machine generates an optical-disc stamper in response to the modulation-result signal. Specifically, the stamper making machine forms projections in a groove or grooves of the optical-disc stamper in accordance with the modulation-result signal. The replicating machine is loaded with the optical-disc stamper. The replicating machine produces virgin optical discs 18 through a molding process using the optical-disc stamper and post-molding processes such as a metalizing process and a coating process. Each produced optical disc 18 has a land or lands corresponding to the above-mentioned groove or grooves of the optical-disc stamper, and land pre-pits corresponding to the above-mentioned projections in the optical-disc stamper.

With reference to FIG. 7, one pre-pit data block has 20 bits. One land pre-pit block is composed of 8 pre-pit data blocks. Therefore, one land pre-pit block has 160 bits in total. Thus, the bits of one land pre-pit block are fewer than those of one prior-art land pre-pit block in FIG. 4. It should be noted that the prior-art land pre-pit block in FIG. 4 has 208 bits in total.

The feature of the land pre-pit block structure in FIG. 7 is that a 3-bit ID information piece is located at the bit positions “9” to “11” extending in a substantially central part of each pre-pit data block. This feature enables the bits of one land pre-pit block to be fewer than those of one prior-art land pre-pit block in FIG. 4 while the trace length for obtaining one piece of information (data) is equal to that in the case of the prior-art design of FIG. 4.

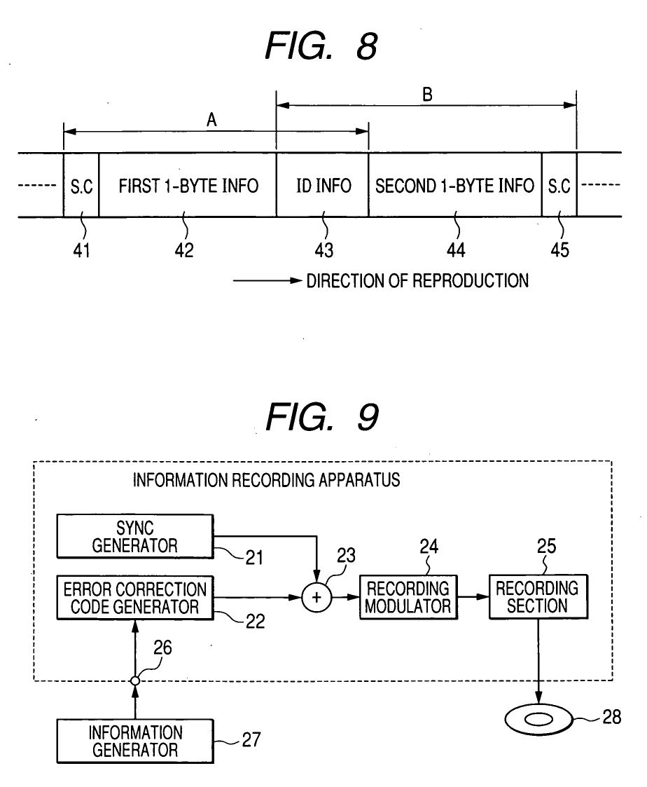

An optical-disc drive device can reproduce information from the land pre-pits in the optical disc 18 while scanning the optical disc 18. As shown in FIG. 8, a 1-bit pre-pit sync signal (sync code S. C) 41 at the head of a pre-pit data block, a first 1-byte information piece 42 at the bit positions “1” to “8” in the pre-pit data block, a 3-bit ID information piece 43 at the bit positions “9” to “11” in the pre-pit data block, a second 1-byte information piece 44 at the bit positions “12” to “19” in the pre-pit data block, a 1-bit pre-pit sync signal (sync code S. C) 45 at the head of a next pre-pit data block, . . . are sequentially reproduced in that order.

The optical-disc drive device can detect every 1-bit pre-pit sync signal and every 3-bit ID information piece in the reproduced information through the use of the fact that the 1-bit pre-pit sync signal and the 3-bit ID information piece take predetermined values. The optical-disc drive device may store information representing the structure of one pre-pit data block.

With reference to FIG. 8, the optical-disc drive device detects the 1-bit pre-pit sync signal 41, the 3-bit ID information piece 43, and the 1-bit pre-pit sync signal 45 in the reproduced information. The optical-disc drive device analyzes the time segment “A” of the reproduced information between the front end of the detected 1-bit pre-pit sync signal 41 and the rear end of the detected 3-bit ID information piece 43. The optical-disc drive device also analyzes the time segment “B” of the reproduced information between the front end of the detected 3-bit ID information piece 43 and the rear end of the detected 1-bit pre-pit sync signal 45. By referring to the structure of one pre-pit data block, the optical-disc drive device recognizes the time segment of the reproduced information between the rear end of the detected 1-bit pre-pit sync signal 41 and the front end of the detected 3-bit ID information piece 43 to be a first 1-byte information piece 42 in the present pre-pit data block. Similarly, the optical-disc drive device recognizes the time segment of the reproduced information between the rear end of the detected 3-bit ID information piece 43 and the front end of the detected 1-bit pre-pit sync signal 45 to be a second 1-byte information piece 44 in the present pre-pit data block.

Accordingly, the 3-bit ID information piece 43 can be used for detecting not only the first 1-byte information piece 42 but also the second 1-byte information piece 44 in the pre-pit data block. Therefore, the trace length for obtaining one piece of information (the first 1-byte information piece 42 or the second 1-byte information piece 44) is equal to that for reproducing the information segment “A” or “B”. Thus, the trace length for obtaining one piece of information is equal to 12 bits, and is the same as that in the case of the prior-art design of FIG. 4. As previously mentioned, the bits of one land pre-pit block are fewer than those of one prior-art land pre-pit block in FIG. 4.

### Second Embodiment

FIG. 9 shows an information recording apparatus according to a second embodiment of this invention.

The apparatus of FIG. 9 includes a sync generator 21, an error correction code generator 22, an adder 23, a recording modulator 24, a recording section 25, and an input terminal 26.

The sync generator 21 produces a 1-bit pre-pit sync signal (a 1-bit pre-pit sync code) taking a predetermined value or state. The sync generator 21 feeds the produced 1-bit pre-pit sync signal to the adder 23. Subsequently, the error correction code generator 22 successively feeds a first 1-byte information piece, a 4-bit error correction code word (a parity “1”), a 3-bit ID information piece, a second 1-byte information piece, and a 4-bit error correction code word (a parity “2”) to the adder 23. In this way, the 1-bit pre-pit sync signal, the first 1-byte information piece, the parity “1”, the 3-bit ID information piece, the second 1-byte information piece, and the parity “2” are sequentially fed to the adder 23. The first and second 1-byte information pieces are generated by an external information generator 27, and are transmitted therefrom to the error correction code generator 22 via the input terminal 26. The 1-bit pre-pit sync signal, the first 1-byte information piece, the parity “1”, the 3-bit ID information piece, the second 1-byte information piece, and the parity “2” are sequentially connected or combined by the adder 23 in that order to form a pre-pit data block. The adder 23 outputs the pre-pit data block.

It should be noted that the external information generator 27 may be provided within the apparatus of FIG. 9.

The sequential feed of the 1-bit pre-pit sync signal, the first 1-byte information piece, the parity “1”, the 3-bit ID information piece, the second 1-byte information piece, and the parity “2” to the adder 23 is repeated 8 times so that 8 pre-pit data blocks constituting one land pre-pit block are sequentially generated by and outputted from the adder 23. The first 1-byte information piece, the parity “1”, the 3-bit ID information piece, the second 1-byte information piece, and the parity “2” are updated for each pre-pit data block. The above-mentioned set of operation steps to generate one land pre-pit block is periodically iterated so that land pre-pit blocks are sequentially generated by and outputted from the adder 23.

The pre-pit data blocks are of a fixed length. In addition, the land pre-pit blocks are of a fixed length.

The parity “1” in each pre-pit data block is designed for error correction about a code word composed of the first 1-byte information piece and the 3-bit ID information piece therein. The parity “2” in each pre-pit data block is designed for error correction about a code word composed of the second 1-byte information piece and the 3-bit ID information piece therein.

The 3-bit ID information piece in each pre-pit data block includes an ID for the pre-pit data block or an ID information piece representing the types of the first 1-byte information piece and the second 1-byte information piece in the pre-pit data block. The 3-bit ID information piece in each pre-pit data block may include an address information piece representing the address of the pre-pit data block relative to the related land pre-pit block. The 3-bit ID information piece in each pre-pit data block takes one among predetermined values or states.

The first 1-byte information piece in each pre-pit data block represents, for example, a portion of an ECC block address, a portion of a parity, or a field ID. The second 1-byte information piece in each pre-pit data block represents, for example, a portion of an ECC block address or a portion of a parity.

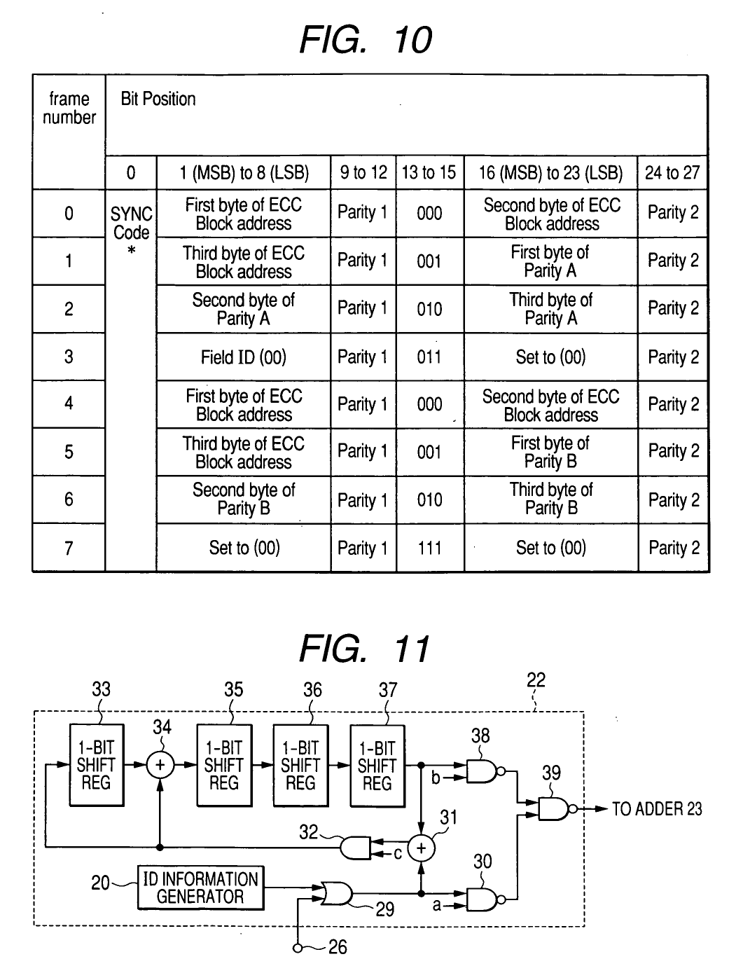

FIG. 10 shows an example of the structure of one land pre-pit block outputted from the adder 23. Land pre-pit blocks are classified according to field ID. The structure of FIG. 10 is applied to a land pre-pit block having a field ID of “00000000”.

As shown in FIG. 10, one land pre-pit block is composed of 8 pre-pit data blocks each having 28 bits. The 8 pre-pit data blocks are assigned frame numbers “0”, “1”, . . . , “7” respectively. In each pre-pit data block, the bit positions are denoted by “0”, “1”, . . . , “27” respectively along the direction from MSB to LSB. In each pre-pit data block, the 1-bit pre-pit sync signal (the 1-bit pre-pit sync code), the first 1-byte information piece, the 4-bit parity “1”, the 3-bit ID information piece, the second 1-byte information piece, and the 4-bit parity “2” are successively arranged. The 1-bit pre-pit sync signal occupies the bit position “0”. The first 1-byte information piece occupies the bit position “1” to the bit position “8”. The 4-bit parity “1” occupies the bit position “9” to the bit position “12”. The 3-bit ID information piece occupies the bit position “13” to the bit position “15”. The second 1-byte information piece occupies the bit position “16” to the bit position “23”. The 4-bit parity “2” occupies the bit position “24” to the bit position “27”.

The first and second 1-byte information pieces, and the 3-bit ID information pieces in FIG. 10 are similar to those in FIG. 7.

With reference back to FIG. 9, the recording modulator 24 receives an output signal (a sequence of land pre-pit blocks) from the adder 23. The recording modulator 24 subjects the output signal from the adder 23 to modulation of a predetermined system. Thereby, the recording modulator 24 converts the output signal from the adder 23 into a modulation-result signal of a prescribed format. The recording modulator 24 feeds the modulation-result signal to the recording section 25. The recording section 25 makes an optical disc 28 in response to the modulation-result signal. Specifically, the recording section 25 records the modulation-result signal on a land or lands of the optical disc 28 as land pre-pits therein. Accordingly, the land or lands of the optical disc 28 has land pre-pits representing the modulation-result signal. The recording section 25 is similar to the recording section 16 in FIG. 6.

The optical disc 28 is a recording medium. The optical disc 28 is, for example, a DVD-RW (Digital Versatile Disc Rewritable). The optical disc 28 may have at least one groove and at least one land similar to those in FIG. 1. The pre-pits are formed in the land or lands of the optical disc 28. These land pre-pits are grouped into sets each having three adjacent land pre-pits which may be similar to the land pre-pits b0, b1, and b2 in FIG. 1.

With reference to FIG. 10, the 3-bit ID information piece in each pre-pit data block includes an ID information piece representing the types of the first 1-byte information piece and the second 1-byte information piece in the pre-pit data block. Thereby, it is possible to place necessary information pieces in a land pre-pit block while arranging the placed information pieces in any one of possible sequences.

The error correction code generator 22 may be designed to generate Hamming code words through the use of the primitive polynomial G(x)=x⁴+x+1. In this case, as shown in FIG. 11, the error correction code generator 22 includes an ID information generator 20, a 2-input OR circuit 29, 2-input NAND circuits 30, 38, and 39, 2-input adders 31 and 34, a 2-input AND circuit 32, and 1-bit shift resisters 33, 35, 36, and 37.

For every pre-pit data block, the ID information generator 20 produces a 3-bit ID information piece, and feeds the produced 3-bit ID information piece to one input terminal of the OR circuit 29. For every pre-pit data block, the external information generator 27 (see FIG. 9) successively feeds first and second 1-byte information pieces to the other input terminal of the OR circuit 29 via the apparatus input terminal 26; The first and second 1-byte information pieces and the 3-bit ID information piece are passed through the OR circuit 29 before being sequentially applied to one input terminal of the NAND circuit 30 and one input terminal of the adder 31 in a prescribed order. A control signal “a” is fed to the other input terminal of the NAND circuit 30 from a first control signal generator (not shown). The other input terminal of the adder 31 receives an output signal from the 1-bit shift register 37.

One input terminal of the AND circuit 32 receives an output signal from the adder 31. A control signal “c” is fed to the other input terminal of the AND circuit 32 from a second control signal generator (not shown). An output signal from the AND circuit 32 is applied to the input terminal of the 1-bit shift register 33 and one input terminal of the adder 34. An output signal from the 1-bit shift register 33 is applied to the other input terminal of the adder 34.

An output signal from the adder 34 is fed to the input terminal of the 1-bit shift register 35. An output signal from the 1-bit shift register 35 is fed to the input terminal of the 1-bit shift register 36. An output signal from the 1-bit shift register 36 is fed to the input terminal of the 1-bit shift register 37. One input terminal of the NAND circuit 38 receives the output signal from the 1-bit shift register 37. A control signal “b” is fed to the other input terminal of the NAND circuit 38 from a third control signal generator (not shown).

One input terminal of the NAND circuit 39 receives an output signal from the NAND circuit 30. The other input terminal of the NAND circuit 39 receives an output signal from the NAND circuit 38. An output signal from the NAND circuit 39 is applied to the adder 23 in FIG. 9 as an output signal from the error correction code generator 22.

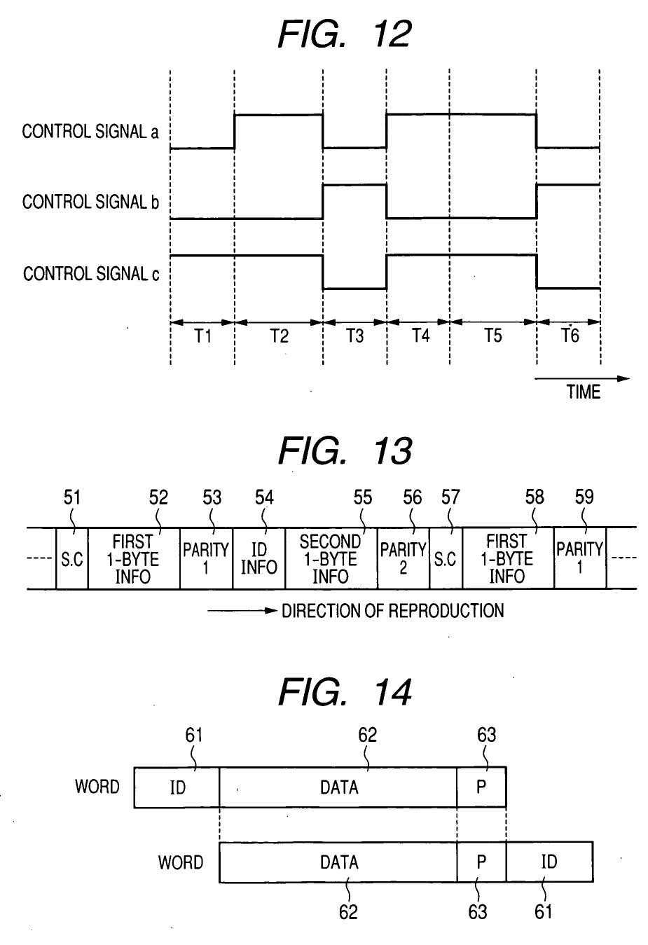

The first, second, and third control signal generators respond to a common clock signal. The first control signal generator is designed so that the control signal “a” will have a waveform shown in FIG. 12. The second control signal generator is designed so that the control signal “c” will have a waveform shown in FIG. 12. The third control signal generator is designed so that the control signal “b” will have a waveform shown in FIG. 12.

With reference to FIG. 12, during a time interval T1, the control signals “a” and “b” are in their low-level states (inactive states) while the control signal “c” is in its high-level state (active state). The AND circuit 32 is opened by the active control signal “c” and the ID information generator 20 is activated so that a 3-bit ID information piece travels from the ID information generator 20 to the 1-bit shift register 33 and the adder 34 via the OR circuit 29, the adder 31, and the AND circuit 32.

During a time interval T2 immediately following the time interval T1, the control signal “b” is in its inactive state while the control signals “a” and “c” are in their active states. The AND circuit 32 and the NAND circuit 30 are opened by the active control signals “c” and “a”, respectively. The ID information generator 20 is deactivated while the external information generator 27 is activated. Therefore, a first 1-byte information piece travels from the external information generator 27 to the 1-bit shift register 33 and the adder 34 via the input terminal 26, the OR circuit 29, the adder 31, and the AND circuit 32. The NAND circuit 39 is opened by the output signal from the NAND circuit 38. Therefore, the first 1-byte information piece travels from the external information generator 27 to the adder 23 via the input terminal 26, the OR circuit 29, and the NAND circuits 30 and 39.

The combination of the devices 31-37 serves to generate a 4-bit error correction code word (a parity “1”) for the 3-bit ID information piece and the first 1-byte information piece. The generated parity “1” can be outputted from the 1-bit shift register 37 to the NAND circuit 38.

During a time interval T3 subsequent to the time interval T2, the control signals “a” and “c” are in their inactive states while the control signal “b” is in its active state. The NAND circuit 30 and the AND circuit 32 are closed by the inactive control signals “a” and “c”, respectively. The external information generator 27 is deactivated. The NAND circuit 38 is opened by the active control signal “b”. The NAND circuit 39 is opened by the output signal from the NAND circuit 30. Therefore, the parity “1” travels from the 1-bit shift register 37 to the adder 23 via the NAND circuits 38 and 39.

During a time interval T4 immediately following the time interval T3, the control signal “b” is in its inactive state while the control signals “a” and “c” are in their active states. The AND circuit 32 and the NAND circuit 30 are opened by the active control signals “c” and “a”, respectively. The ID information generator 20 is activated. Therefore, the 3-bit ID information piece travels from the ID information generator 20 to the 1-bit shift register 33 and the adder 34 via the OR circuit 29, the adder 31, and the AND circuit 32. The NAND circuit 39 is opened by the output signal from the NAND circuit 38. Therefore, the 3-bit ID information piece travels from the ID information generator 20 to the adder 23 via the OR circuit 29 and the NAND circuits 30 and 39.

During a time interval T5 subsequent to the time interval T4, the control signal “b” is in its inactive state while the control signals “a” and “c” are in their active states. The AND circuit 32 and the NAND circuit 30 are opened by the active control signals “c” and “a”, respectively. The ID information generator 20 is deactivated while the external information generator 27 is activated. Therefore, a second 1-byte information piece travels from the external information generator 27 to the 1-bit shift register 33 and the adder 34 via the input terminal 26, the OR circuit 29, the adder 31, and the AND circuit 32. The NAND circuit 39 is opened by the output signal from the NAND circuit 38. Therefore, the second 1-byte information piece travels from the external information generator 27 to the adder 23 via the input terminal 26, the OR circuit 29, and the NAND circuits 30 and 39.

The combination of the devices 31-37 serves to generate a 4-bit error correction code word (a parity “2”) for the 3-bit ID information piece and the second 1-byte information piece. The generated parity “2” can be outputted from the 1-bit shift register 37 to the NAND circuit 38.

During a time interval T6 immediately following the time interval T5, the control signals “a” and “c” are in their inactive states while the control signal “b” is in its active state. The NAND circuit 30 and the AND circuit 32 are closed by the inactive control signals “a” and “c”, respectively. The external information generator 27 is deactivated. The NAND circuit 38 is opened by the active control signal “b”. The NAND circuit 39 is opened by the output signal from the NAND circuit 30. Therefore, the parity “2” travels from the 1-bit shift register 37 to the adder 23 via the NAND circuits 38 and 39.

In this way, the first 1-byte information piece, the 4-bit parity “1”, the 3-bit ID information piece, the second 1-byte information piece, and the 4-bit parity “2” are sequentially outputted from the error correction code generator 22 to the adder 23.

An optical-disc drive device can reproduce information from the land pre-pits in the optical disc 28 while scanning the optical disc 28. As shown in FIG. 13, a 1-bit pre-pit sync signal (sync code S. C) 51 at the head of a pre-pit data block, a first 1-byte information piece 52 at the bit positions “1” to “8” in the pre-pit data block, a parity 53 (a parity “1”) at the bit positions “9” to “12” in the pre-pit data block, a 3-bit ID information piece 54 at the bit positions “13” to “15” in the pre-pit data block, a second 1-byte information piece 55 at the bit positions “16” to “23” in the pre-pit data block, a parity 56 (a parity “2”) at the bit positions “24” to “27” in the pre-pit data block, a 1-bit pre-pit sync signal (sync code S. C) 57 at the head of a next pre-pit data block, . . . are sequentially reproduced in that order.

In the land pre-pit block structure of FIG. 10, error correction about the first and second 1-byte information pieces can be implemented provided that error correction about the related 3-bit ID information pieces has been completed. For every pre-pit data block, each of the parities “1” and “2” are generated in consideration of the related 3-bit ID information piece. The parity “1” is designed for error correction about the first-byte information piece and the 3-bit ID information piece, whereas the parity “2” is designed for error correction about the second-byte information piece and the 3-bit ID information piece. Although the positions of the first and second 1-byte information pieces relative to the position of the 3-bit ID information piece are different in every pre-pit data block, both the parities “1” and “2” are generated by the same error correction code generator 22.

In every pre-pit data block, the set of the first 1-byte information piece 52, the parity 53, and the 3-bit ID information piece 54, and the set of the 3-bit ID information piece 54, the second 1-byte information piece 55, and the parity 56 are of a cyclic-type Hamming code. The optical-disc drive device includes a known Hamming-code error detection and correction circuit, which implements not only error detection and correction about the set of the first 1-byte information piece 52, the parity 53, and the 3-bit ID information piece 54 but also error detection and correction about the set of the 3-bit ID information piece 54, the second 1-byte information piece 55, and the parity 56.

According to the land pre-pit block structure in FIG. 10, the trace length for obtaining one piece of information (data) is approximately equal to 16 bits. Therefore, the reproduction of recorded information and the error correction for the reproduced information can be implemented with a reasonable trace length. Thus, the land pre-pit block structure in FIG. 10 is useful for search.

According to the prior-art land pre-pit block structure in FIG. 4, the error correction for the ECC block address can be implemented provided that the six successive pre-pit data blocks containing the ECC block address and the parity have been read out. On the other hand, according to the land pre-pit block structure in FIG. 10, the error correction for a 1-byte portion of the ECC block address can be implemented provided that the 15-bit set of the first or second 1-byte information piece, the parity “1” or “2”, and the 3-bit ID information piece has been read out. Therefore, the land pre-pit block structure in FIG. 10 is more useful for search than that in FIG. 4 is.

In the land pre-pit block of FIG. 10, the ECC block address and the parity (the parity “A” or “B”) are duplicated. After the first 1-byte information piece, the parity “1”, and the 3-bit ID information piece in every pre-pit data block are read out, the optical-disc drive device implements the error correction about the first 1-byte information piece and the 3-bit ID information piece in response to the parity “1”. After the 3-bit ID information piece, the second 1-byte information piece, and the parity “2” in every pre-pit data block are read out, the optical-disc drive device implements the error correction about the second 1-byte information piece and the 3-bit ID information piece in response to the parity “2”. The optical-disc drive device combines the error-corrected first and second 1-byte information pieces in the 6 successive pre-pit data blocks to reconstruct the 6 bytes indicating the first, second, and third bytes of the ECC block address, and the first, second, and third bytes of the parity “A” (or the parity “B”). Thereafter, the optical-disc drive device implements the error correction about the ECC block address in response to the parity “A” (or the parity “B”). As a result, the ECC block address is subjected to the double error correction. Thus, it is possible to more accurately recover the original state of the ECC block address.

During a short time interval at and around a track jump in search, the states or values of higher bytes of successive read-out ECC block addresses remain equal to each other. According to the prior-art land pre-pit block structure in FIG. 4, the error correction for the ECC block address can be implemented provided that the six successive pre-pit data blocks up to one containing the third byte of the parity have been read out. On the other hand, according to the land pre-pit block structure in FIG. 10, the error correction for a 1-byte portion of the ECC block address can be implemented provided that the 15-bit set of the first or second 1-byte information piece, the parity “1” or “2”, and the 3-bit ID information piece has been read out. Furthermore, as previously mentioned, it is possible to more accurately recover the original state of the ECC block address. Even in the event that higher bytes of a currently-accessed ECC block address fail to be detected after a track jump, higher bytes of a previously-accessed ECC block address can be used as those of the currently-accessed ECC block address. Therefore, the land pre-pit block structure in FIG. 10 is suited for detection of a currently-accessed ECC block address during search.

### Third Embodiment

A third embodiment of this invention is similar to the second embodiment thereof except for design changes mentioned hereafter. The third embodiment of this invention uses a self-synchronizable code or a linear cyclic error correction code such as a comma-free code.

One word of the comma-free code consists of 36 successive bits expressed as “1, 1, 1, 1, 1, 1, 0, D1, D2, D3, D4, D5, 0, D6, D7, D8, P1, P2, 0, P3, P4, ID1, ID2, ID3, E1, E2, E3, E4, E5, E6, E7, E8, Q1, Q2, Q3, Q4”, where 7 successive bits “1, 1, 1, 1, 1, 1, 0” at the head of the word constitute a sync information piece of a fixed pattern, and the sixth and twelfth bits counted from the end of the sync information piece are mandatorily “0”. The bits D1-D8 are assigned to the first 1-byte information piece. The bits E1-E8 are assigned to the second 1-byte information piece. The bits P1-P4 are assigned to the 4-bit parity “1”. The bits Q1-Q4 are assigned to the 4-bit parity “2”. The bits ID1-ID3 are assigned to the 3-bit ID information piece.

An optical-disc drive device can obtain the sync information piece from read-out information by detecting the values or states of the 19 successive bits “1, 1, 1, 1, 1, 1, 0, D1, D2, D3, D4, D5, 0, D6, D7, D8, P1, P2, 0” (that is, “1, 1, 1, 1, 1, 1, 0, X, X, X, X, X, 0, X, X, X, X, X, 0”) therein, where X denotes either “1” or “0”.

With reference to FIG. 14, there are a first sub word formed by a sequence of the first 1-byte information piece 62, the parity 63 (the parity “1”), and the 3-bit ID information piece 61, and a second sub word formed by a sequence of the 3-bit ID information piece 61, the second 1-byte information piece 62, and the parity 63 (the parity “2”). The first and second sub words are of a same code. Thus, in the optical-disc drive device, a same error detection and correction circuit can implement not only error correction about the first sub word but also error correction about the second sub word.

Specifically, there are a first sub word composed of the bits D1 -D8 representative of the first 1-byte information piece, the bits P1-P4 representative of the parity “1”, and the bits ID1-ID3 representative of the 3-bit ID information piece, and a second sub word composed of the bits ID-ID3 representative of the 3-bit ID information piece, the bits E1-E8 representative of the second 1-byte information piece, and the bits Q1-Q4 representative of the parity “2”. The first and second sub words are of a same code. Thus, in the optical-disc drive device, a same error detection and correction circuit can implement not only error correction about the first sub word but also error correction about the second sub word. It is possible to efficiently add the error correction code to information recorded on an optical disc as land pre-pits therein.

### Fourth Embodiment

A fourth embodiment of this invention is a generalization of the first embodiment thereof. According to the fourth embodiment of this invention, every pre-pit data block is composed of a 1-bit pre-pit sync signal, “n-m” 1-byte information pieces following the 1-bit pre-pit sync signal, an ID information piece following the “n-m” 1-byte information pieces, and “m” 1-byte information pieces following the ID information piece, where “n” denotes a natural number equal to or greater than 2, and “m” denotes a natural number smaller than “n” and equal to or greater than 1. The ID information piece is placed in an intermediate portion of the pre-pit data block.

### Fifth Embodiment

A fifth embodiment of this invention is a generalization of the second or third embodiment thereof. According to the fifth embodiment of this invention, every pre-pit data block is composed of a 1-bit pre-pit sync signal, “n-m” 1-byte information pieces following the 1-bit pre-pit sync signal, a first error correction code signal following the “n-m” 1-byte information pieces, an ID information piece following the first error correction code signal, “m” 1-byte information pieces following the ID information piece, and a second error correction code signal following the “m” 1-byte information pieces, where “n” denotes a natural number equal to or greater than 2, and “m” denotes a natural number smaller than “n” and equal to or greater than 1. The first error correction code signal is designed for error correction about the “n-m” 1-byte information pieces and the ID information piece. The second error correction code signal is designed for error correction about the “m” 1-byte information pieces and the ID information piece. The ID information piece is designed for identification about the types of the “n-m” 1-byte information pieces and the “m” 1-byte information pieces. The ID information piece is placed in an intermediate portion of the pre-pit data block.

### Sixth Embodiment

A sixth embodiment of this invention is similar to the second, third, or fifth embodiment thereof except that one of cyclic codes different from the Hamming code is used as the error correction code.

### Seventh Embodiment

A seventh embodiment of this invention is similar to one of the first to sixth embodiments thereof except for a design change mentioned hereafter. The seventh embodiment of this invention is designed to implement the recording of an information signal on the groove or grooves in an optical disc rather than the recording of information on the optical disc as land pre-pits therein.

### Eighth Embodiment

An eighth embodiment of this invention is similar to one of the first to seventh embodiments thereof except for a design change mentioned hereafter. The eighth embodiment of this invention is designed to record information on a recording medium different from an optical disc.

What is claimed is:

1. A method of recording information on a recording medium, comprising the steps of:
repetitively generating a fixed-length block including a sync information piece, “n-m” information pieces following the sync information piece, an ID information piece following the “n-m” information pieces, and “m” information pieces following the ID information piece, wherein “n” denotes a natural number equal to or greater than 2, and “m” denotes a natural number smaller than “n” and equal to or greater than 1; and
recording the generated fixed-length block on the recording medium;
wherein the ID information piece is placed in an intermediate portion of the fixed-length block.

2. A method of recording information on a recording medium, comprising the steps of:
repetitively generating a fixed-length block including a sync information piece, “n-m” information pieces following the sync information piece, a first error correction code signal following the “n-m” information pieces, an ID information piece following the first error correction code signal, “m” information pieces following the ID information piece, and a second error correction code signal following the “m” information pieces, wherein “n” denotes a natural number equal to or greater than 2, and “m” denotes a natural number smaller than “n” and equal to or greater than 1, wherein the first error correction code signal is for error correction about the “n-m” information pieces and the ID information piece, and the second error correction code signal is for error correction about the “m” information pieces and the ID information piece, and wherein the ID information piece is for identification about types of the “n-m” information pieces and the “m” information pieces; and
recording the generated fixed-length block on the recording medium;
wherein the ID information piece is placed in an intermediate portion of the fixed-length block.

3. A method as recited in claim 2, wherein the “n-m” information pieces, the first error correction code signal, and the ID information piece constitute a first linear cyclic error correction code word, and the ID information piece, the “m” information pieces, and the second error correction code signal constitute a second linear cyclic error correction code word.

4. An apparatus for recording information on a recording medium, comprising:
means for repetitively generating a fixed-length block including a sync information piece, “n-m” information pieces following the sync information piece, an ID information piece following the “n-m” information pieces, and “m” information pieces following the ID information piece, wherein “n” denotes a natural number equal to or greater than 2, and “m” denotes a natural number smaller than “n” and equal to or greater than 1; and
means for recording the generated fixed-length block on the recording medium;
wherein the ID information piece is placed in an intermediate portion of the fixed-length block.

5. An apparatus for recording information on a recording medium, comprising:
means for repetitively generating a fixed-length block including a sync information piece, “n-m” information pieces following the sync information piece, a first error correction code signal following the “n-m” information pieces, an ID information piece following the first error correction code signal, “m” information pieces following the ID information piece, and a second error correction code signal following the “m” information pieces, wherein “n” denotes a natural number equal to or greater than 2, and “m” denotes a natural number smaller than “n” and equal to or greater than 1, wherein the first error correction code signal is for error correction about the “n-m” information pieces and the ID information piece, and the second error correction code signal is for error correction about the “m” information pieces and the ID information piece, and wherein the ID information piece is for identification about types of the “n-m” information pieces and the “m” information pieces; and
means for recording the generated fixed-length block on the recording medium;
wherein the ID information piece is placed in an intermediate portion of the fixed-length block.

6. An apparatus as recited in claim 5, wherein the “n-m” information pieces, the first error correction code signal, and the ID information piece constitute a first linear cyclic error correction code word, and the ID information piece, the “m” information pieces, and the second error correction code signal constitute a second linear cyclic error correction code word.
